(19) United States
(12) Patent Application Publication
(10) Pub. No.: US 2017/0369991 A1
(43) Pub. Date: Dec. 28, 2017

(54) METAL COMPOSITE STRUCTURE AND PROCESS FOR PRODUCING THE SAME

(71) Applicant: Alexander Michael Derderian, Grand Blanc, MI (US)

(72) Inventor: Alexander Michael Derderian, Grand Blanc, MI (US)

(21) Appl. No.: 15/630,602

(22) Filed: Jun. 22, 2017

Related U.S. Application Data
(60) Provisional application No. 62/353,309, filed on Jun. 22, 2016.

(51) Int. Cl. C23C 16/06; C22C 23/00; C23C 16/02; C23C 16/56

(52) U.S. Cl. CPC C23C 16/06; C23C 16/56; C22C 23/00; C23C 16/0227

(57) ABSTRACT

A magnesium alloy composite structure includes a magnesium alloy substrate, a zinc layer applied to the magnesium alloy substrate, a copper layer applied to the zinc layer, a nickel strike layer applied to the copper layer; an autocatalytic nickel layer applied to the nickel strike layer and a surface layer applied to the autocatalytic nickel layer. Various surface layers include Aluminum Titanium Nitride, Boron Nitride, Chromium Nitride, Titanium Nitride, Zirconium Nitride, Zirconium Oxide, Zirconium Oxycarbide, Titanium Carbide, Titanium Nitride and Diamond Like Carbon.

### CROSS-REFERENCE TO RELATED APPLICATIONS

This application claims priority of U.S. Provisional Patent Application Ser. No. 62/353,309, filed Jun. 22, 2016, the entire contents of which are incorporated herein by reference.

### FIELD OF THE INVENTION

The invention relates to metal composite layered materials for magnesium substrates.

### BACKGROUND OF THE INVENTION

Magnesium and its alloys possess desirable properties such as a high strength and low density, together with high-temperature and low electromagnetic conductivity. Magnesium is an abundant metal with high manufacturability to form simple and complex geometries with relative ease. This high degree of manufacturability couples with its environmentally friendly nature and high specific strength makes it an ideal candidate for automotive, aerospace, electronics, defense, and many other industry applications alike.

Magnesium in its elemental state is reactive and is often alloyed with other materials to reduce its reactivity. Most notably, it is magnesium's reactivity and material structure that makes it susceptible to corrosion and abrasion. It is therefore desirable to enhance the properties of a magnesium substrate material by applying coating layers to increase the corrosion resistance, enhance the hardness and wear resistance, and apply a decorative finish to the substrate.

As such, there is an apparent need, within the appreciable art, for a coated magnesium composite material with enhanced properties and a process of manufacturing a coated magnesium composite material.

### SUMMARY OF THE INVENTION

In one aspect there is disclosed a process of forming a magnesium metal composite comprising the steps of: providing a magnesium alloy substrate; depositing a layer of zinc conversion coating onto the magnesium alloy substrate using a zinc immersion in an alkaline solution; depositing a layer of copper onto the zinc layer using an electrolytic copper cyanide solution having an acidic additive; depositing a layer of nickel phosphorous onto the copper layer using an autocatalytic nickel solution forming a nickel strike and forming a subsequent nickel phosphorous layer on the nickel strike; depositing a subsequent autocatalytic nickel phosphorous layer onto the initial nickel phosphorous layer deposited in the nickel strike solution; and depositing a layer of a surface coating onto the nickel layer by means of either chemical vapor deposition or physical vapor deposition.

In one aspect there is disclosed a process of forming a magnesium metal composite comprising the steps of: providing a magnesium alloy substrate; depositing a layer of zinc conversion coating onto the magnesium alloy substrate using a zinc immersion in an alkaline solution; depositing a layer of copper onto the zinc layer using an electrolytic copper cyanide solution having an acidic additive; depositing a layer of nickel phosphorous onto the copper layer using an autocatalytic nickel solution forming a nickel strike and forming a subsequent nickel phosphorous layer on the nickel strike; depositing a subsequent autocatalytic nickel phosphorous layer onto the initial nickel phosphorous layer deposited in the nickel strike solution; depositing an electrolytic nickel layer onto the autocatalytic phosphorous nickel; depositing two copper layers, separated by a drying and polishing process, by means of a bright acid copper solution onto the surface of the electrolytic nickel layer; depositing electrolytic bright or satin nickel on the surface of the copper; and depositing a layer of a surface coating onto the nickel layer by means of either chemical vapor deposition or physical vapor deposition.

In one aspect there is disclosed a process of forming a magnesium metal composite comprising the steps of: providing a magnesium alloy substrate; depositing a layer of zinc conversion coating onto the magnesium alloy substrate using a zinc immersion in an alkaline solution; depositing a layer of copper onto the zinc layer using an electrolytic copper cyanide solution having an acidic additive; depositing a layer of nickel phosphorous onto the copper layer using an autocatalytic nickel solution forming a nickel strike and forming a subsequent nickel phosphorous layer on the nickel strike; depositing a subsequent autocatalytic nickel phosphorous layer onto the initial nickel phosphorous layer deposited in the nickel strike solution; depositing an electrolytic nickel layer onto the autocatalytic phosphorous nickel; depositing two copper layers, separated by a drying and polishing process, by means of a bright acid copper solution onto the surface of the electrolytic nickel layer; depositing electrolytic bright or satin nickel on the surface of the copper; depositing a layer of chrome through means of either a trivalent or hexavalent electrolytic chrome solution in various colors onto the electrolytic bright or satin nickel; and depositing a layer of a surface coating onto the nickel layer by means of either chemical vapor deposition or physical vapor deposition.

In another aspect there is disclosed a magnesium alloy composite structure that includes a magnesium alloy substrate, a zinc layer applied to the magnesium alloy substrate, a copper layer applied to the zinc layer, a nickel strike layer applied to the copper layer; an autocatalytic nickel layer applied to the nickel strike layer and a surface layer applied to the autocatalytic nickel layer.

### BRIEF DESCRIPTION OF THE DRAWINGS

FIG. 1A is a partial side view showing the surface of a substrate;

FIG. 1B is a partial side view showing the surface of a substrate;

FIG. 2A is a process flow diagram of steps of forming a composite metal structure;

FIG. 2B is a process flow diagram of steps of forming a composite metal structure;

FIG. 3 is a sectional view showing a composite structure;

FIG. 4 is a sectional view showing a composite structure;

FIG. 5 is a sectional view showing a composite structure;

FIG. 6 is a sectional view showing a composite structure;

FIG. 7 is a sectional view showing a composite structure;

FIG. 8 is a sectional view showing a composite structure;

FIG. 9 is a sectional view showing a composite structure;

FIG. 10 is a sectional view showing a composite structure;

FIG. 11 is a sectional view showing a composite structure;

FIG. 12 is a sectional view showing a composite structure;

FIG. 13 is a sectional view showing a composite structure;

FIG. 14 is a sectional view showing a composite structure;

FIG. 15 is a sectional view showing a composite structure;

FIG. 16 is a sectional view showing a composite structure;

FIG. 17 is a sectional view showing a composite structure;

FIG. 18 is a sectional view showing a composite structure;

FIG. 19 is a sectional view showing a composite structure;

FIG. 20 is a sectional view showing a composite structure;

FIG. 21 is a sectional view showing a composite structure;

FIG. 22 is a sectional view showing a composite structure;

FIG. 23 is a sectional view showing a composite structure.

### DESCRIPTION OF THE EMBODIMENTS

Referring to the figures, there is shown a layered or composite structure that includes a substrate 10 and various additional layers 12 improving the substrate's resistance to abrasive, corrosive, and other destructive elements while offering an aesthetically pleasing appearance. The substrate 10 may be formed of magnesium or magnesium alloys. The substrate 10 may be shaped to a desired geometry utilizing a variety of fabrication methods. The substrate 10 and additional layers 12 may be surface finished in a variety of ways to constitute a progressive geometry with a roughness value that may be contingently based on the part needs. The substrate 10 may include additional layers such as an initial deposit whose primary element is nickel. This nickel plating may be deposited on the surface of the substrate. Following the nickel deposition, a secondary surface finishing step may be completed to alter the parts appearance or increase its' functional value. A second deposition process, typically physical vapor deposition, may then be performed to deposit functional or decorative coatings.

In one aspect, a net geometric part or substrate 10 is formed, molded, cast, or manufactured out of a magnesium alloy. In one aspect, this alloy may be comprised of a variety of magnesium percentages. Examples of magnesium alloys that may be utilized in the process include AZ31B, AM60B, and AZ91D (other material iterations of these proposed materials may be utilized). It should be realized that other magnesium alloys may be utilized under the appropriate conditions. In one aspect, the magnesium alloy may be utilized in ingot, billet, or other material form to be processed to a desired part geometry.

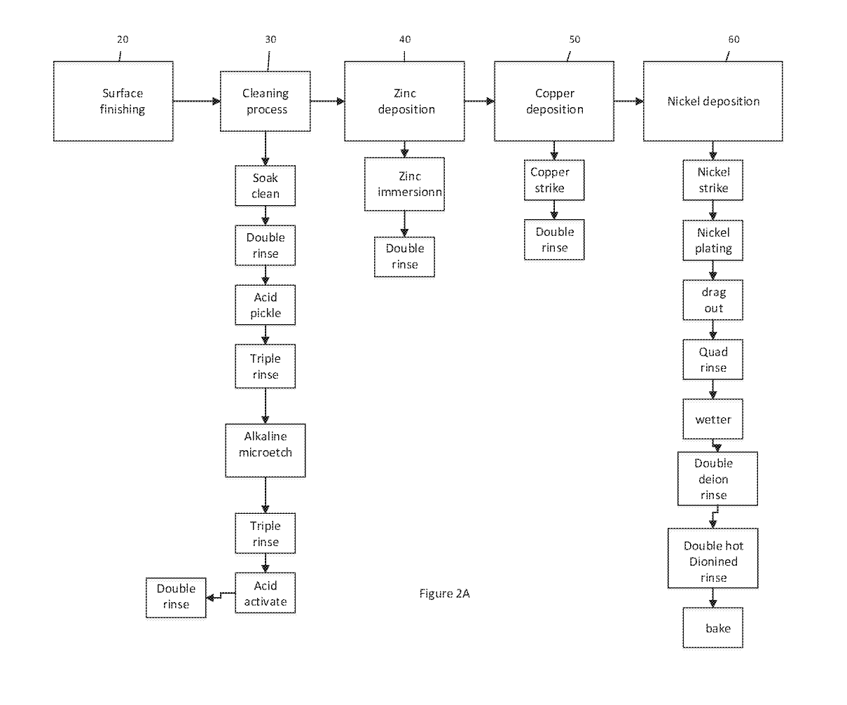

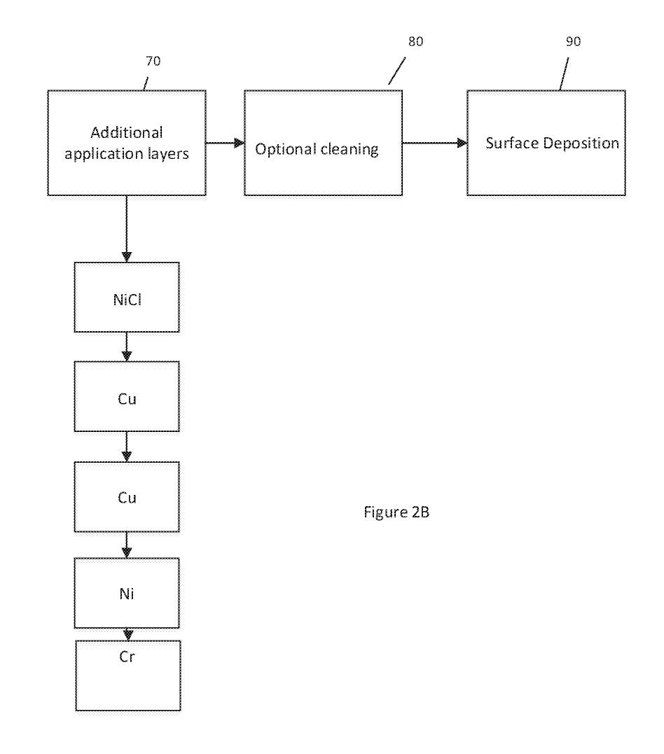

The process of forming the composite metal material will be described with reference to FIGS. 2A and 2B. In one aspect, the net geometric part may be trimmed, cut, machined, formed, pressed, or manufactured in another way. In one aspect, a thixomolding process may be used to mold a part's geometry. Alternatively, sand casting, die casting, or other methods may be used to form the part. In one aspect, trimming of the part may be completed to remove subsequent flashing or unnecessary material from the prior process. Depending on the process flow, machining may be used initially or subsequently in the correct order, as defined by the parts process flow, to create, progress, or complete the parts net geometry. Depending on the process performed, there may be particulates that occlude the pores of the net geometric part. Other occluding materials such as die lubrication, machining lubrication, or other particulates may also be present on the surface. In this scenario, a cleaning process may be completed to prepare the part for the surface finishing or plating processes. There are a variety of cleaning methods, including, vibratory deburring, high energy deburring, and ultrasonic or manual cleaning, that may be used to remove process particulates. Depending on the part's process constraints, a more aggressive deburring step, as previously mentioned, may be used to de-flash, deburr, and clean the part during this stage.

In one aspect, the process may include a material finishing step 20 such as high energy deburring, vibratory finishing, manual deburring, manual polishing, buffing, blasting with various media, or another type of similar process to finish the part. Depending on the process chosen, specific steps may be completed to prepare the parts surface for the first plating deposition process. When polishing is performed various polishing lubrication and media may be used. However, polishing and blasting media containing iron can cause accelerated corrosion in the surface of a magnesium alloy part and should not be utilized.

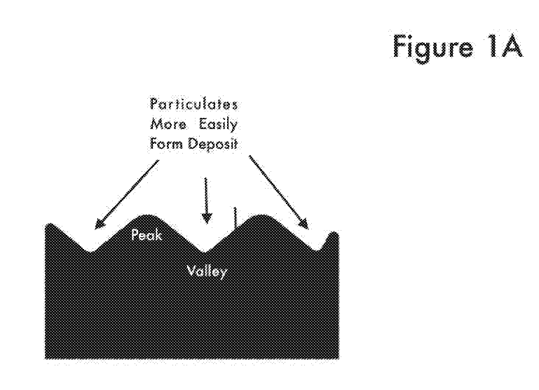

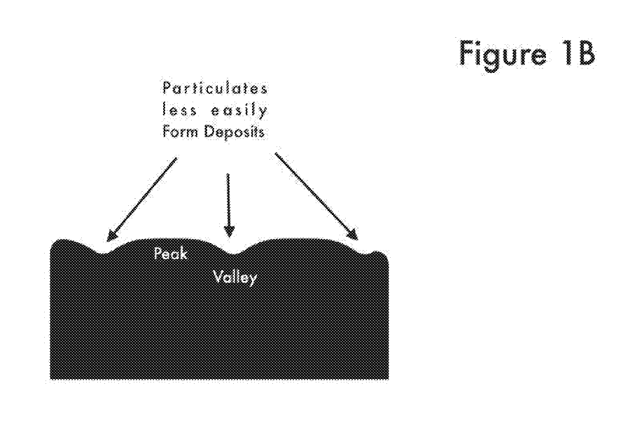

The surface finishing step 20 of the process may serve both decorative and functional roles. Various parameters of the part's use may influence the surface finishing. For example, if it is of importance to have a surface with the highest corrosion resistance, then a low Ra value, which would yield a highly polished surface, would be most beneficial. In this aspect, the highly polished surface will have less peaks and valleys for particulates to deposit and cause corrosion. Displays of the part's surface geometry are shown in FIGS. 1A and 1B.

As a result of the surface finishing step there may be particulates that occlude the pores of the net geometric part. Other occluding material like polishing lubrication, finishing media, or other particulates may also be present on the surface. In one aspect, a cleaning process 30 may be completed to prepare the part for the plating processes. There are a variety of cleaning methods, including heavy-duty solvents and cleaners, ultrasonic cleaners, and others, that may be utilized to prepare the surface. In one aspect, a cleaning method prior to an electroless nickel process would include a heavy-duty soak cleaner to remove the most prevalent particulates like molding compounds, die lube, machining coolants, and polishing compounds. This heavy-duty soak cleaner would be followed by an acid dip then alkaline micro-etch cleaner.

The cleaning step may include the following steps: A) The surface of the magnesium alloy substrate is pre-cleaned with an alkaline cleaning solution to remove surface particulates. B) Magnesium alloy substrate is pickled in either a hydrofluoric or oxalic acid solution to removes surface particulates and conditions the surface by removing material. C) A heavy duty degreasing soak further removes any organic contamination on the surface of the magnesium alloy substrate. D) A alkaline based etching solution micro etches the surface by removing material from the magnesium alloy substrate. E) An acid activator is used to remove the oxidation layer from the micro etch while encouraging a homogenous magnesium rich surface by removing other elements within the surface of the alloyed substrate.

After this pre-clean sequence 30 is completed, the magnesium alloy substrate 10 surface has been prepared for the first layer of deposition. The following depositions are then made in sequential order onto the surface of the magnesium alloy substrate as shown in FIGS. 2A and 2B: I) A zinc conversion coating 14 is deposited onto the magnesium alloy substrate through a zinc immersion bath. The zinc immersion bath is a highly alkaline solution. II) A layer of copper 16 is deposited onto the surface of the zinc conversion coating 14 through an electrolytic copper cyanide bath with an acidic additive to prevent the attack of any exposed magnesium. The use of live entry into the copper cyanide bath at very low amperage negates the removal of zinc from the surface. III) A layer of nickel strike 18 is deposited onto the surface of the copper layer 16 through an autocatalytic nickel solution. For the first segment of plating within this solution, the use of anodic and cathodic processing is necessary to initiate the deposition. The first segment requiring this anodic and cathodic initiation will vary depending on the square footage of plating required within this stage. The final segment relies on the autocatalytic nature of the nickel strike solution to build to the required thickness of the deposit. IV) A layer of autocatalytic nickel 22 is deposited onto the surface of the nickel strike 18 layer. The phosphorous content of the autocatalytic nickel can vary depending on the application's needs.

At this stage, there are a multitude of different process flows, disclosed herein after, that can be employed depending on the application's needs. If the application requires a polished, decorative surface, then the following process flow may be followed: V) A layer of electrolytic nickel (nickel chloride) 26 is deposited onto the surface of the autocatalytic nickel 22. VI) A layer of electrolytic bright acid copper 28 is deposited onto the surface of the electrolytic nickel (nickel chloride) 26. The bright acid copper layer 28 is then dried and polished to increase the surface brightness and clarity. The polished bright acid copper layer, possibly retaining surface contamination from the polishing process, is then soak cleaned and activated with an acid activator. VII) A second layer of electrolytic bright acid copper 32 is deposited on the first layer of bright acid copper 28. At this stage, the application will dictate whether a satin or bright appearance is needed. VIII) A layer of electrolytic nickel (either bright or satin) 34 is deposited onto the surface of the bright acid copper layer 32. Finally, again dictated by the needs of the application, a chrome layer 36 may be applied, in various colors, including traditional chrome, black chrome, Galvano silver chrome, or another shade of chrome. The shade of chrome necessitated by the application does not impact the chrome layer deposition. IX) A layer of electrolytic chrome (traditional, black, Galvano silver, or another color) is deposited onto the surface of the electrolytic nickel (bright or satin). If the application does not require a polished finish, then further depositions used for leveling and polishing are not necessary. Regardless of the depositions needs, the final deposition or surface layer 24 is as follows. X) A thin film layer is deposited using vapor deposition. There are two types of vapor deposition that can be utilized: a) Physical vapor deposition of the following thin film layers (it is important to note that other thin film layer depositions through physical vapor deposition are possible on this material): i) Aluminum Titanium Nitride ii) Boron Nitride iii) Chromium Nitride iv) Titanium Nitride v) Zirconium Nitride, Zirconium Oxide, or Zirconium Oxycarbide b) Chemical vapor deposition of the following thin film layers (it is important to note that other thin film layer depositions through chemical vapor deposition are possible on this material): i)Titanium Carbide ii) Titanium Nitride iii) Diamond Like Carbon

Table 1.1 presented below includes the deposition layers as described above and indicates the deposition type and thickness ranges for each of the layers.

TABLE 1.1

| | | Deposition | |
|---|---|---|---|
| Deposition Number | Deposition | Chemical | Thickness |
| (in consecutive order) | Type | Formula | (inches) |
| Deposition 1 | Zinc | Zn | 0.000005- |
| | | | 0.000008 |
| Deposition 2 | Copper | Cu | 0.00005- |
| | | | 0.00015 |
| Deposition 3 | Nickel | NiP | 0.000035- |
| | Phosphorous | | 0.00015 |
| Deposition 4 | Nickel | NiP | 0.0003-No |
| | Phosphorous | | Limit |
| Deposition 5 | Nickel | NiCl | 0.00003- |
| | | | 0.000075 |
| Deposition 6 | Copper | Cu | 0.0006-No |
| | | | Limit |
| Deposition 7 | Copper | Cu | 0.0003-No |
| | | | Limit |
| Deposition 8 | Nickel | Ni | 0.00015-No |
| | | | Limit |
| Deposition 9 | Chrome | Cr | 0.000005- |
| | | | 0.000015 |
| Deposition | PVD | Various | Up to 0.00002 |
| 10a | (Various) | | |
| Deposition | CVD | Various | Up to 0.00002 |
| 10b | (Various) | | |

Table 2.1 includes examples of the various layers for: Zinc Conversion Coating, Copper Cyanide Strike, Autocatalytic Nickel Strike, Autocatalytic Nickel, Physical Vapor Deposition (Various Types).

TABLE 2.1

| Deposition Type 1 | Deposition Type 2 | Deposition Type 3 | Deposition Type 4 | Deposition Type 5 |
|---|---|---|---|---|
| Magnesium Alloy | Magnesium Alloy | Magnesium Alloy | Magnesium Alloy | Magnesium Alloy |
| Zn | Zn | Zn | Zn | Zn |
| Cu | Cu | Cu | Cu | Cu |
| Ni—P | Ni—P | Ni—P | Ni—P | Ni—P |
| Ni—P | Ni—P | Ni—P | Ni—P | Ni—P |
| AlTiN | BN | CrN | TiN | ZrN/ZrO/ZrOC |

Table 2.2 includes examples of the various layers for: Zinc Conversion Coating, Copper Cyanide Strike, Autocatalytic Nickel Strike, Autocatalytic Nickel, Chemical Vapor Deposition (Various Types).

TABLE 2.2

| Deposition Type 7 | Deposition Type 8 |
|---|---|
| Magnesium Alloy | Magnesium Alloy |
| Zn | Zn |
| Cu | Cu |
| Ni—P | Ni—P |
| Ni—P | Ni—P |
| TiN | DLC |

Table 2.3 includes examples of the various layers for: Zinc Conversion Coating, Copper Cyanide Strike, Autocatalytic Nickel Strike, Autocatalytic Nickel, Electrolytic Nickel (Nickel Chloride), Electrolytic Bright Acid Copper, Electrolytic Bright Nickel or Satin Nickel, Physical Vapor Deposition (Various Types).

TABLE 2.3

| Deposition Type 6 | Deposition Type 7 | Deposition Type 8 | Deposition Type 9 | Deposition Type 10 |
|---|---|---|---|---|
| Magnesium Alloy | Magnesium Alloy | Magnesium Alloy | Magnesium Alloy | Magnesium Alloy |
| Zn | Zn | Zn | Zn | Zn |
| Cu | Cu | Cu | Cu | Cu |
| Ni—P | Ni—P | Ni—P | Ni—P | Ni—P |
| Ni—P | Ni—P | Ni—P | Ni—P | Ni—P |
| Ni—P | Ni—P | Ni—P | Ni—P | Ni—P |
| Cu | Cu | Cu | Cu | Cu |
| Ni | Ni | Ni | Ni | Ni |
| AlTiN | BN | CrN | TiN | ZrN/ZrO/ZrOC |

Table 2.4 includes examples of the various layers for: Zinc Conversion Coating, Copper Cyanide Strike, Autocatalytic Nickel Strike, Autocatalytic Nickel, Electrolytic Nickel (Nickel Chloride), Electrolytic Bright Acid Copper, Electrolytic Bright Nickel or Satin Nickel, Chemical Vapor Deposition (Various Types).

TABLE 2.4

| Deposition Type 7 | Deposition Type 8 |
|---|---|
| Magnesium Alloy | Magnesium Alloy |
| Zinc | Zinc |
| Zn | Zn |
| Cu | Cu |
| Ni—P | Ni—P |
| Ni—P | Ni—P |
| Ni—P | Ni—P |
| Cu | Cu |
| TiN | DLC |

Table 2.5 includes examples of the various layers for: Zinc Conversion Coating, Copper Cyanide Strike, Autocatalytic Nickel Strike, Autocatalytic Nickel, Electrolytic Nickel (Nickel Chloride), Electrolytic Bright Acid Copper, Electrolytic Bright or Satin Nickel, Chrome (Various Types), Physical Vapor Deposition (Various Types).

TABLE 2.5

| Deposition Type 6 | Deposition Type 7 | Deposition Type 8 | Deposition Type 9 | Deposition Type 10 |
|---|---|---|---|---|
| Magnesium Alloy | Magnesium Alloy | Magnesium Alloy | Magnesium Alloy | Magnesium Alloy |
| Zn | Zn | Zn | Zn | Zn |
| Cu | Cu | Cu | Cu | Cu |
| Ni—P | Ni—P | Ni—P | Ni—P | Ni—P |
| Ni—P | Ni—P | Ni—P | Ni—P | Ni—P |
| Ni—P | Ni—P | Ni—P | Ni—P | Ni—P |
| Cu | Cu | Cu | Cu | Cu |
| Ni | Ni | Ni | Ni | Ni |
| Cr | Cr | Cr | Cr | Cr |
| AlTiN | BN | CrN | TiN | ZrN/ZrO/ZrOC |

Table 2.6 includes examples of the various layers for: Zinc Conversion Coating, Copper Cyanide Strike, Autocatalytic Nickel Strike, Autocatalytic Nickel, Electrolytic Nickel (Nickel Chloride), Electrolytic Bright Acid Copper, Electrolytic Bright or Satin Nickel, Chrome (Various Types), Chemical Vapor Deposition (Various Types).

TABLE 2.6

| Deposition Type 7 | Deposition Type 8 |
|---|---|
| Magnesium Alloy | Magnesium Alloy |
| Zn | Zn |
| Cu | Cu |
| Ni—P | Ni—P |
| Ni—P | Ni—P |
| Ni—P | Ni—P |
| Cu | Cu |
| Ni | Ni |
| Cr | Cr |
| TiN | DLC |

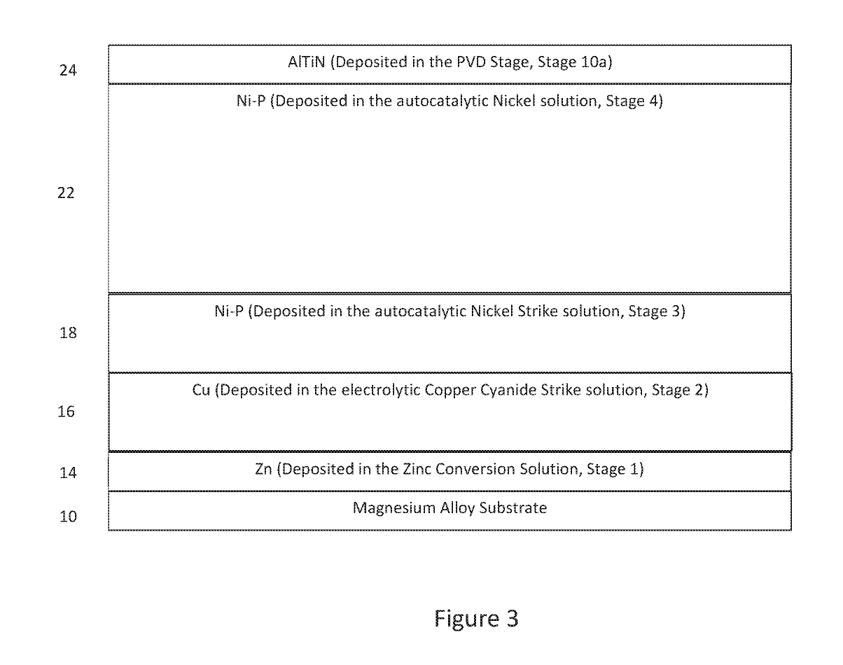

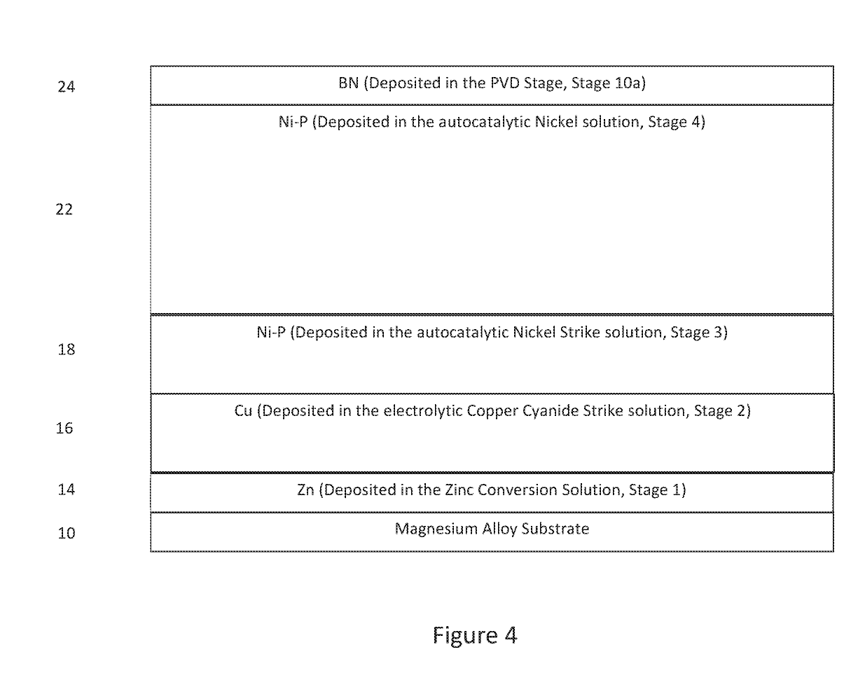

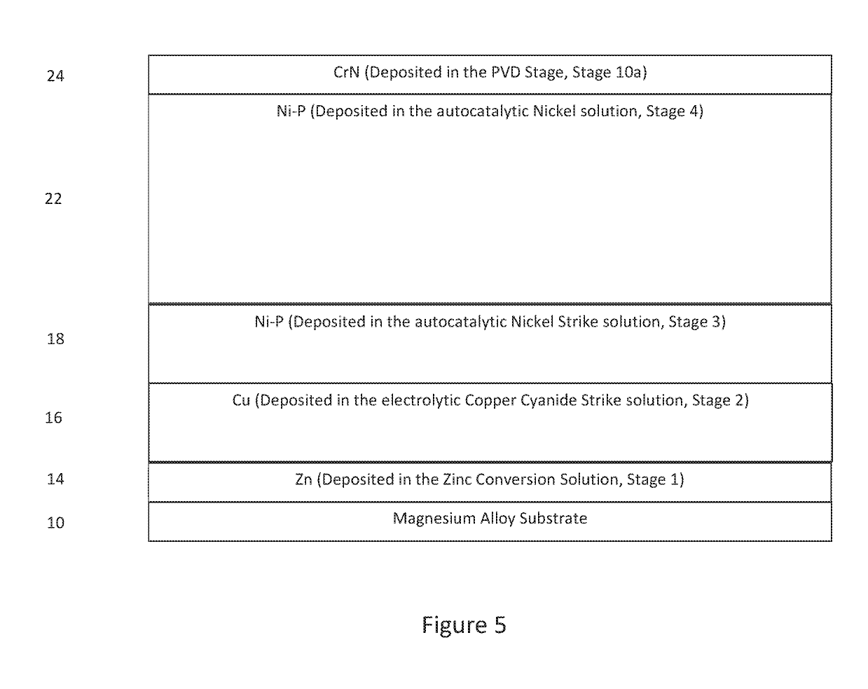

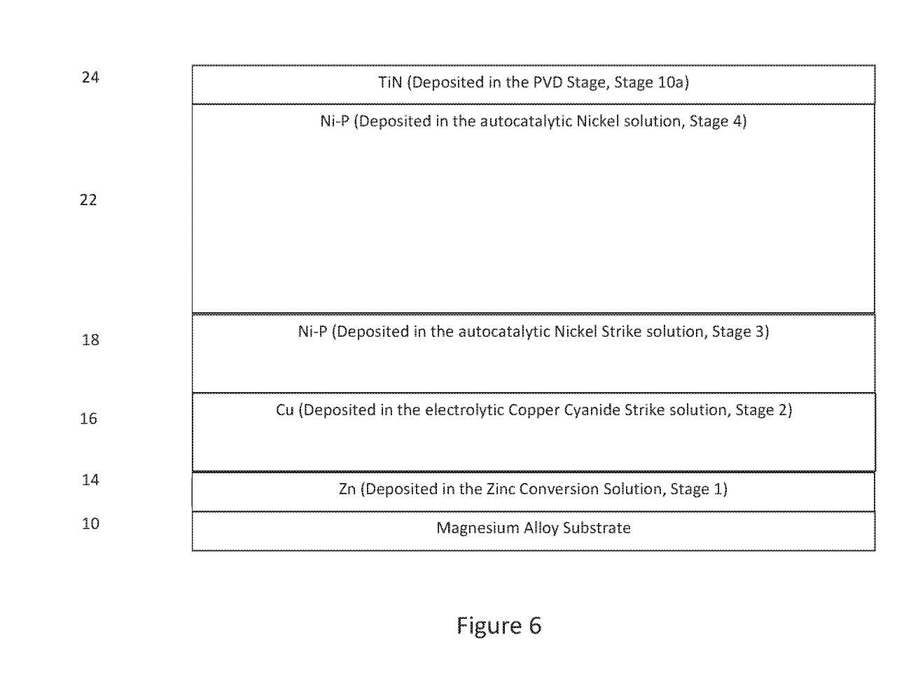

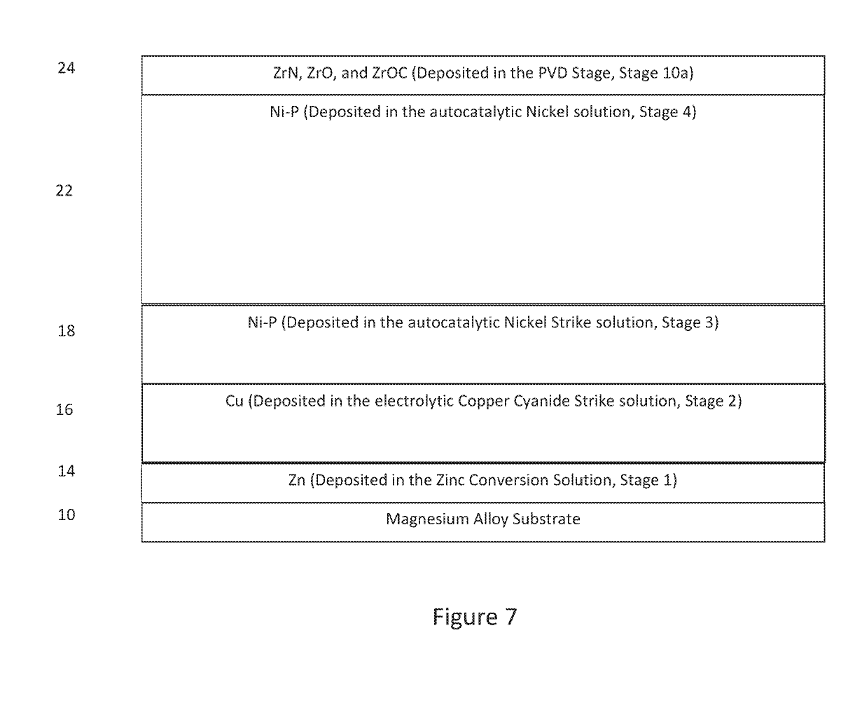

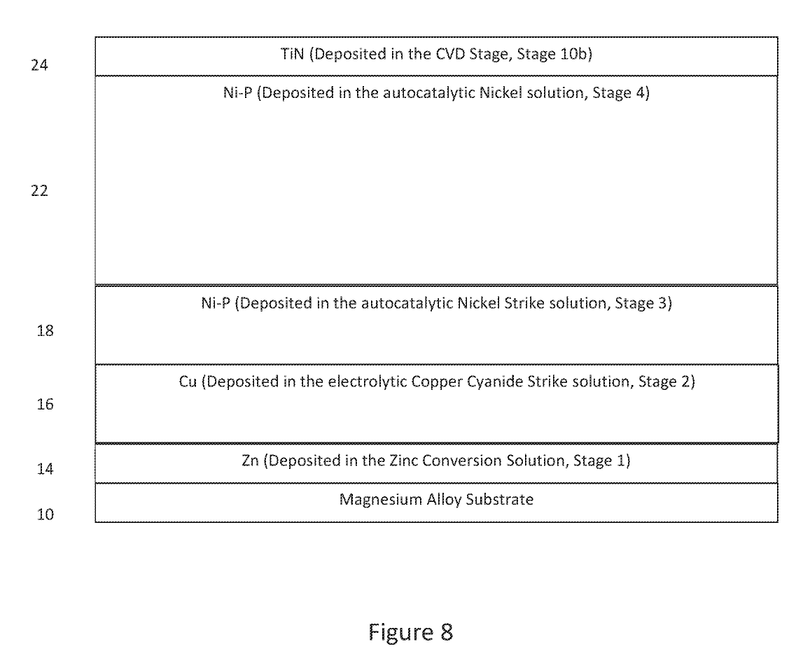

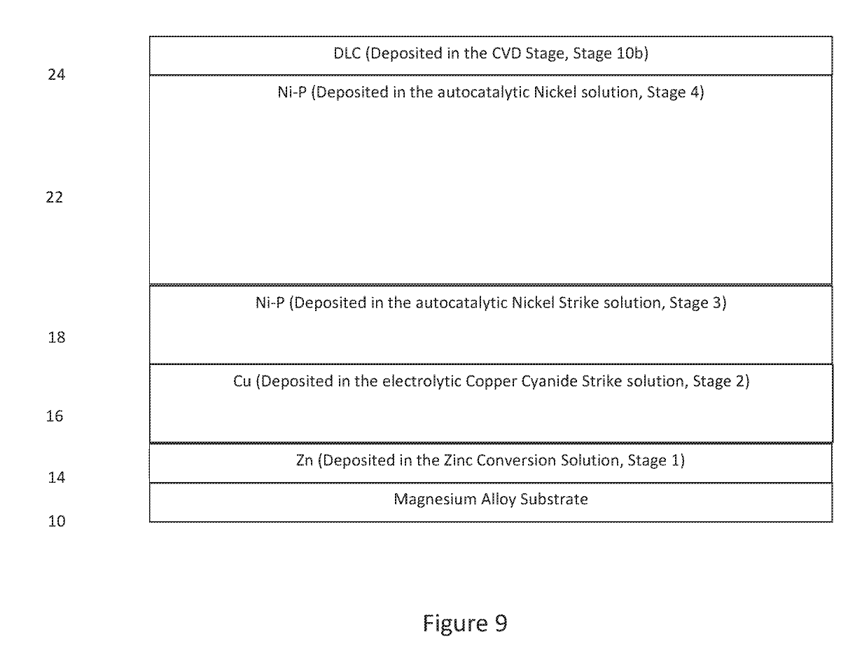

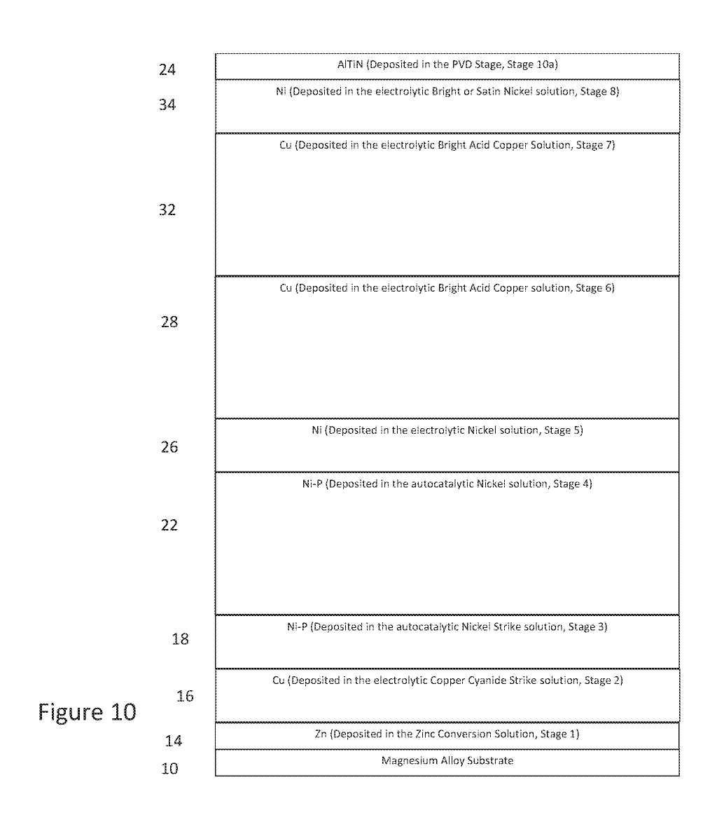

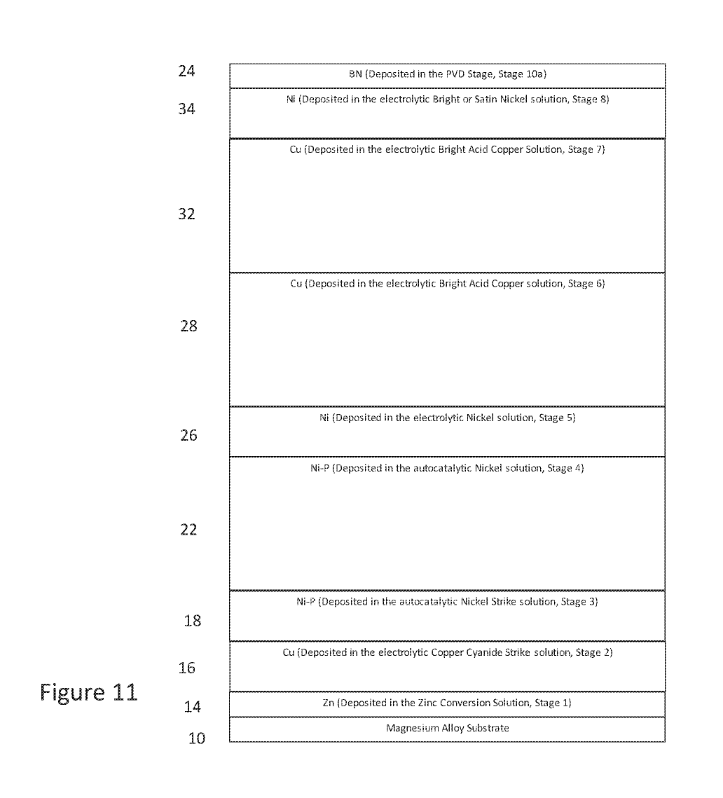

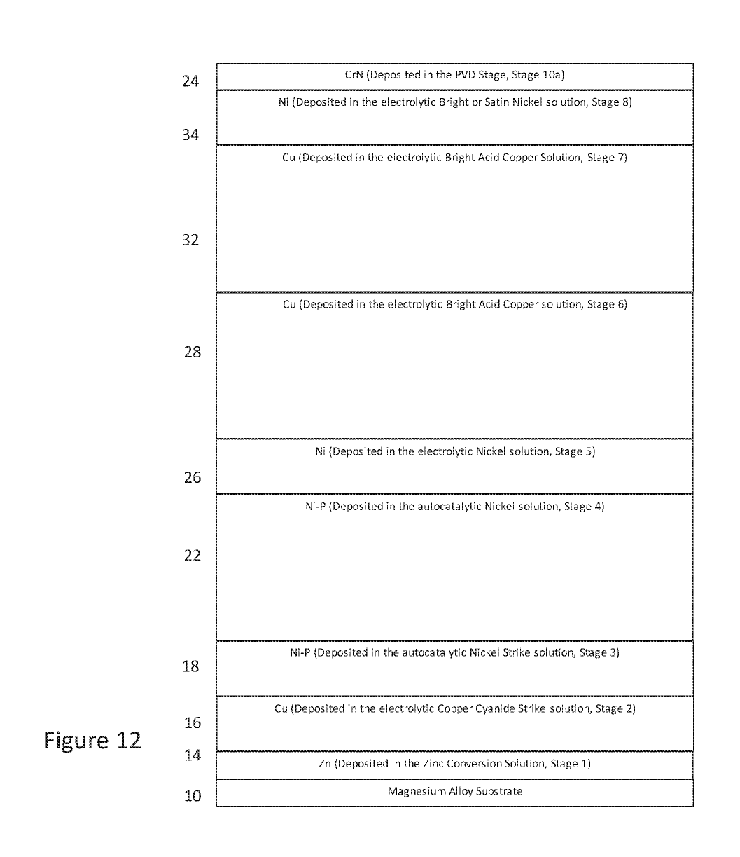

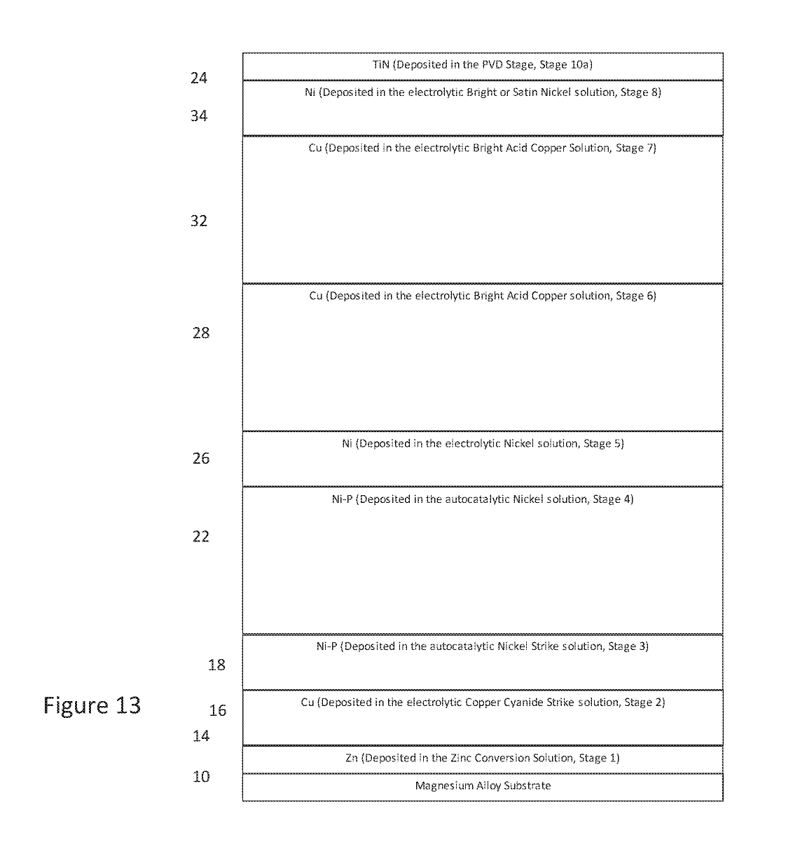

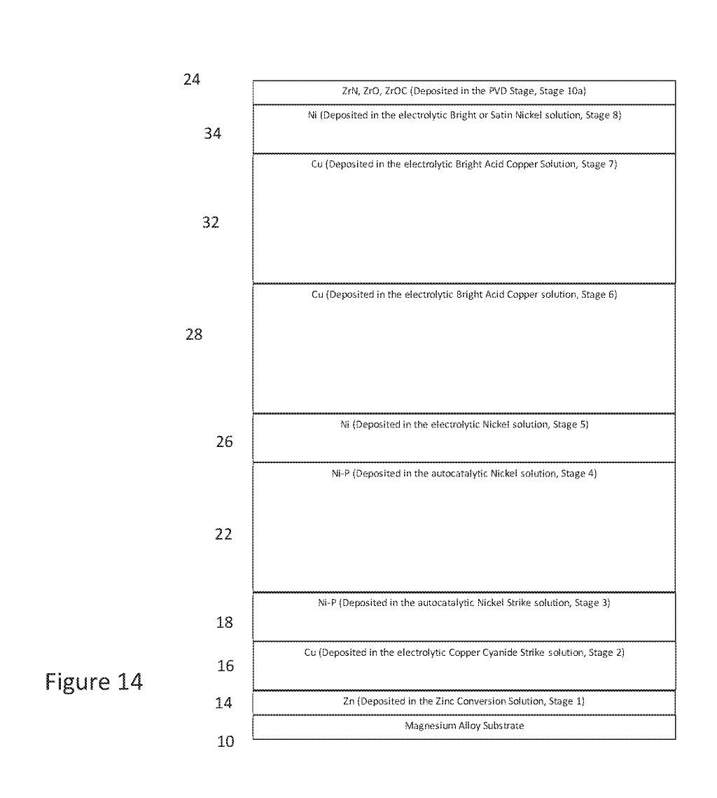

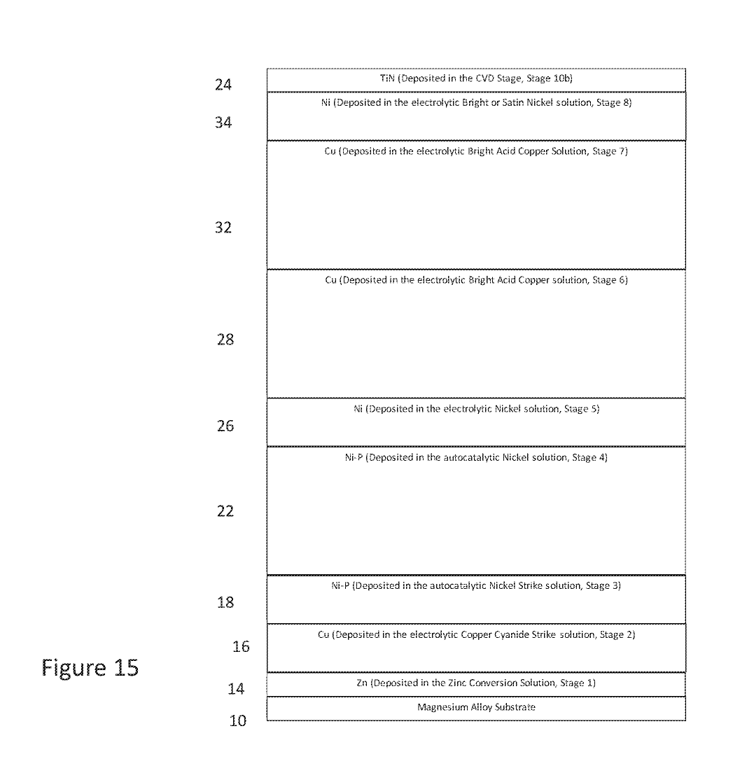

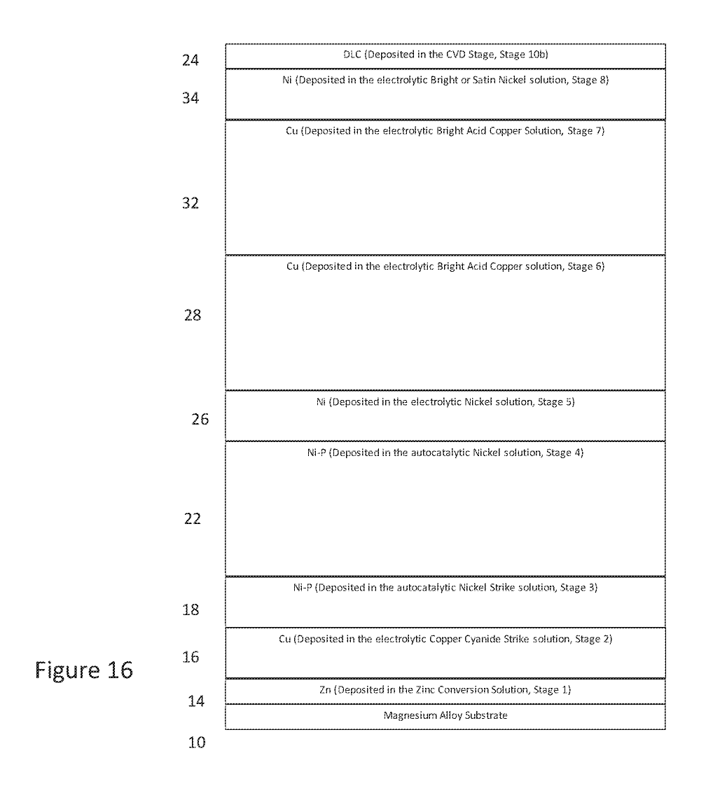

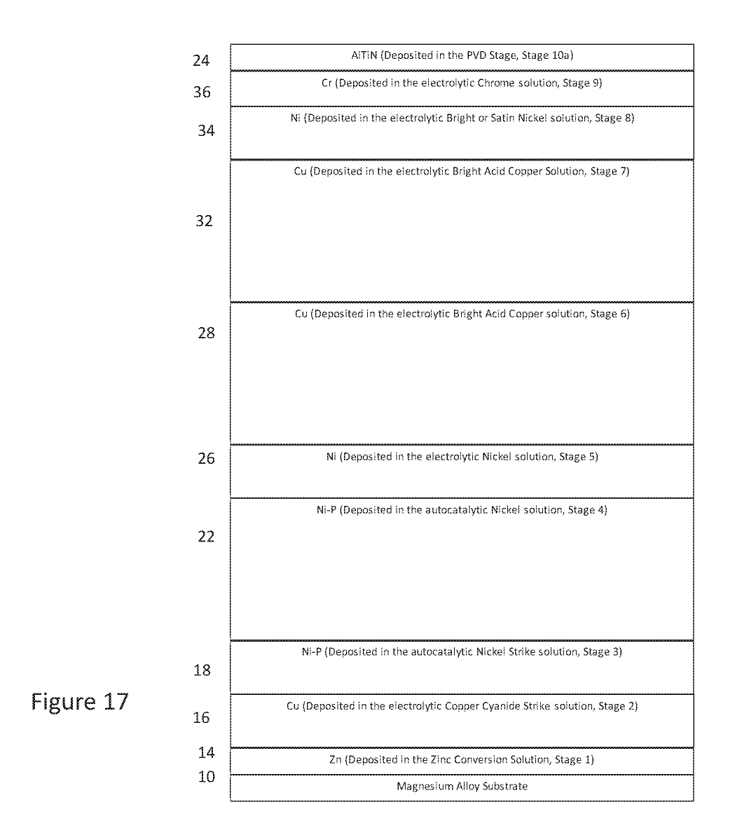

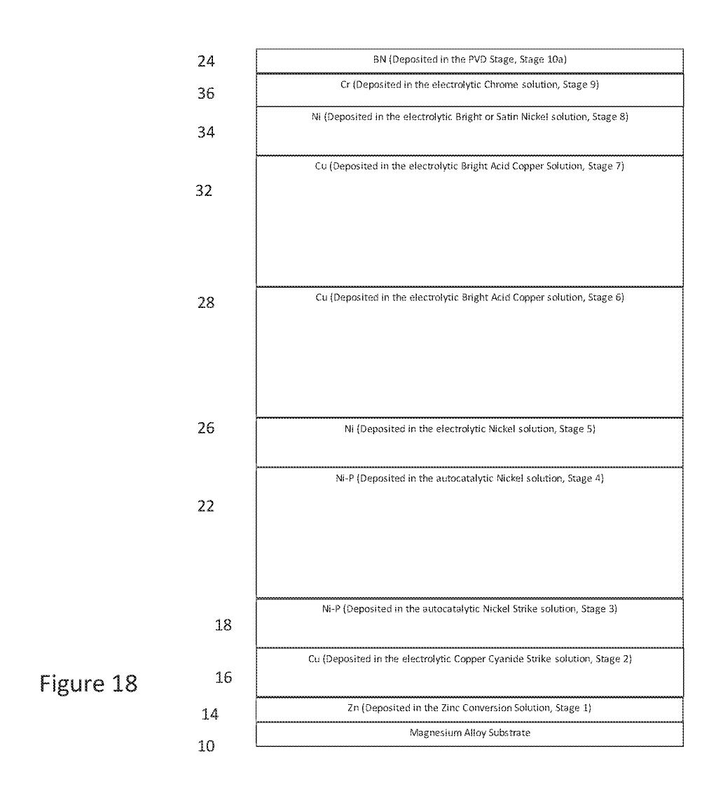

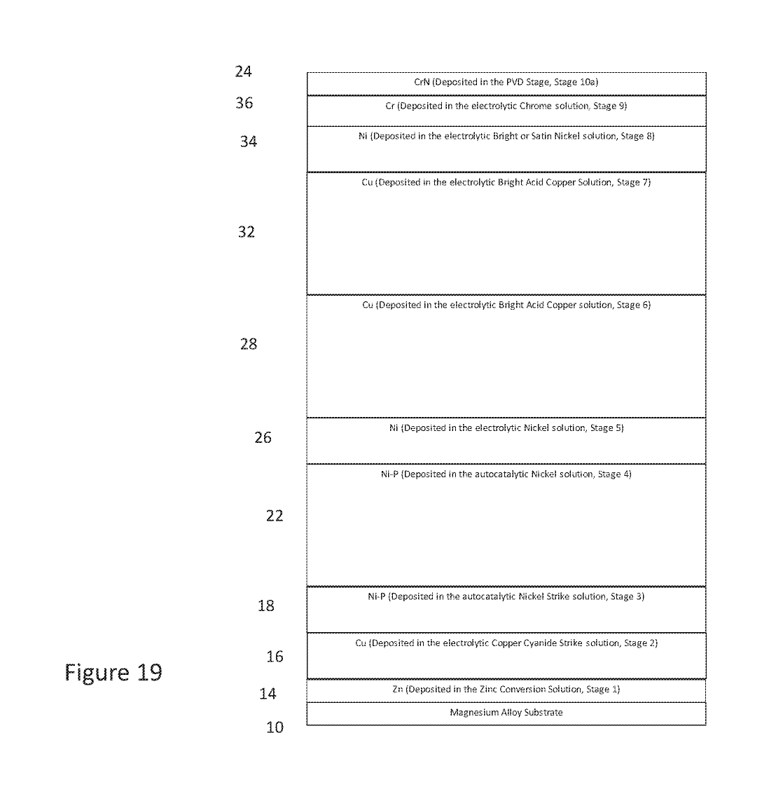

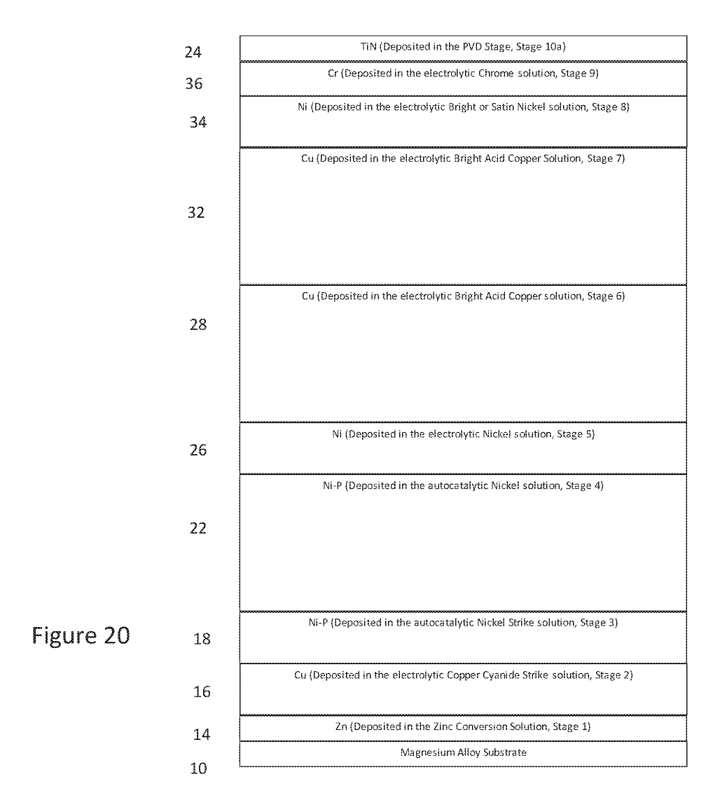

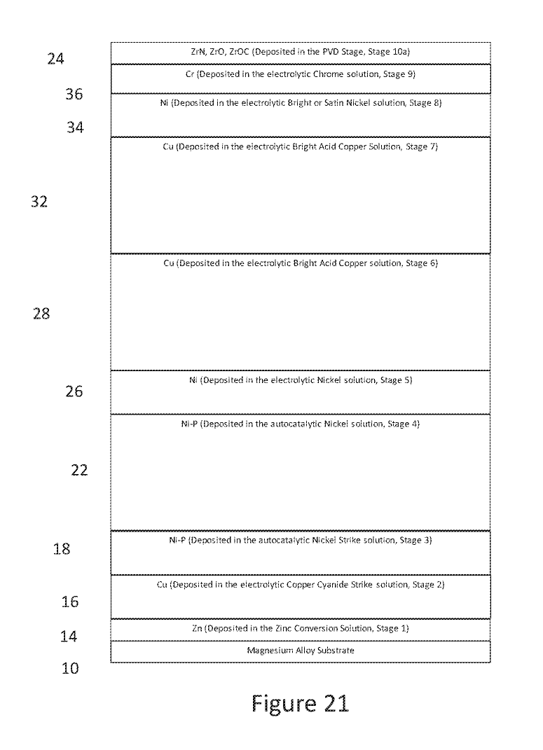

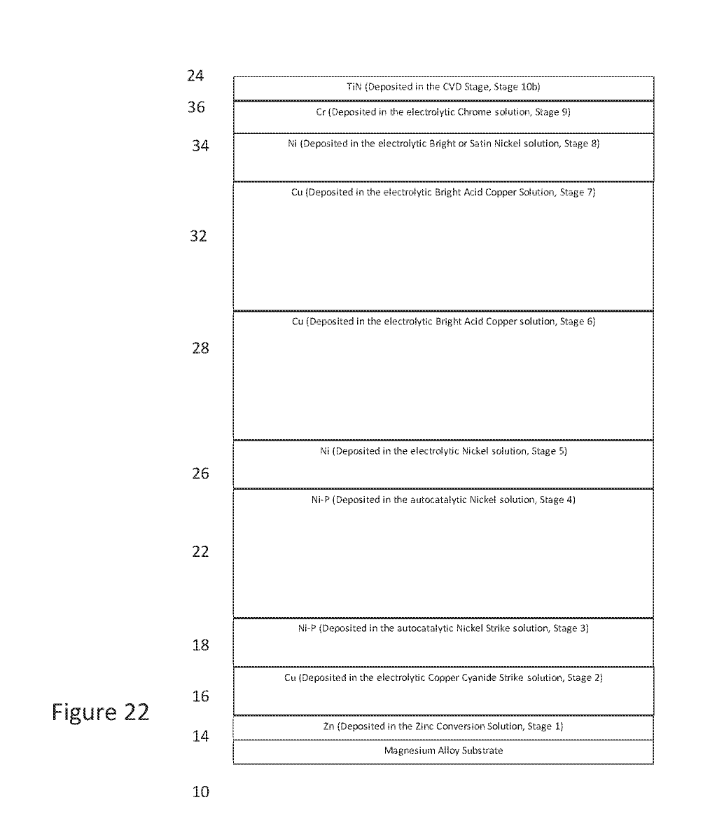

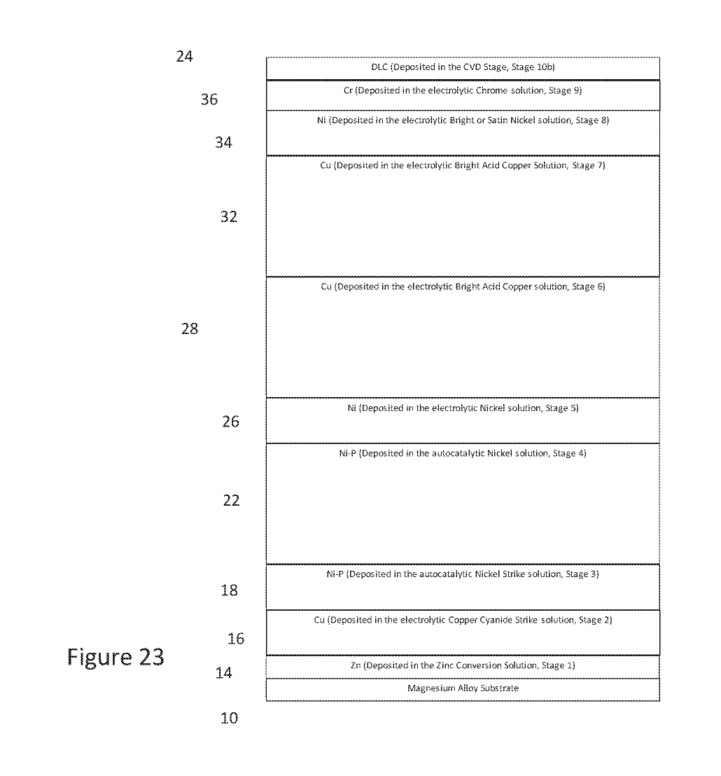

FIGS. 3-23 include sectional views of the layer structures of the various composite structure provided in the tables listed above.

1. A process of forming magnesium metal composite comprising the steps of:
providing a magnesium alloy substrate;
depositing a layer of zinc onto the magnesium alloy substrate using a zinc immersion in an alkaline solution;
depositing a layer of copper onto the zinc layer using an electrolytic copper cyanide bath having an acidic additive,
depositing a layer of nickel onto the copper layer using an autocatalytic nickel solution forming a nickel strike and forming a subsequent nickel layer on the nickel strike, and
depositing a layer of a surface coating onto the nickel layer.

2. The process of claim 1 including the step of finishing and cleaning the magnesium alloy prior to depositing the zinc layer.

3. The process of claim 2 wherein the cleaning step includes applying an alkaline cleaning solution to the magnesium alloy substrate, pickling the magnesium alloy substrate in hydrofluoric or oxalic acid solution, degreasing soak, applying an alkaline etching solution micro etching a surface of the magnesium alloy substrate, applying an acid activator removing an oxidation layer from the micro etch.

4. The process of claim 1 wherein the magnesium alloy is formed of a material having a principal element of magnesium and wherein a minimum magnesium content within the alloy is 85%.

5. The process of claim 1 further including the step of applying a layer of nickel from nickel chloride on to the subsequent layer of nickel.

6. The process of claim 5 further including the step of applying a layer of copper from bright acid copper onto the layer of nickel from nickel chloride.

7. The process of claim 6 further including the step of applying a second layer of copper from bright acid copper onto the layer of copper from bright acid copper.

8. The process of claim 7 further including the step of applying a layer of bright or satin electrolytic nickel to the second layer of copper from bright acid copper.

9. The process of claim 8 further including the step of applying a layer of electrolytic chrome to the layer of bright or satin electrolytic nickel.

10. The process of claim 1 wherein the step of depositing a layer of a surface coating includes vapor depositing a thin layer of a surface coating.

11. The process of claim 10 wherein the vapor deposition includes physical vapor deposition of a material selected from the group consisting of: Aluminum Titanium Nitride, Boron Nitride, Chromium Nitride, Titanium Nitride, Zirconium Nitride, Zirconium Oxide, and Zirconium Oxycarbide.

12. The process of claim 10 wherein the vapor deposition includes chemical vapor deposition of a material selected from the group consisting of: Titanium Carbide, Titanium Nitride and Diamond Like Carbon.

13. A magnesium alloy composite structure comprising:
a magnesium alloy substrate,
a zinc layer applied to the magnesium alloy substrate,
a copper layer applied to the zinc layer,
a nickel strike layer applied to the copper layer;
an autocatalytic nickel layer applied to the nickel strike layer and
a surface layer applied to the autocatalytic nickel layer.

14. The magnesium alloy composite structure of claim 13 wherein the zinc layer has a thickness of from 0.000005 to 0.000008 inches.

15. The magnesium alloy composite structure of claim 13 wherein the copper layer has a thickness of from 0.00005 to 0.00015 inches.

16. The magnesium alloy composite structure of claim 13 wherein the nickel strike layer has a thickness of 0.000035 to 0.00015 inches.

17. The magnesium alloy composite structure of claim 13 further including a layer of nickel from nickel chloride applied to the autocatalytic nickel layer.

18. The magnesium alloy composite structure of claim 17 further including a layer of copper from bright acid copper applied onto the layer of nickel from nickel chloride.

19. The magnesium alloy composite structure of claim 18 further including a second layer of copper from bright acid copper onto the layer of copper from bright acid copper.

20. The magnesium alloy composite structure of claim 19 further including a layer of bright or satin electrolytic nickel applied to the second layer of copper from bright acid copper.

21. The magnesium alloy composite structure of claim 20 further including a layer of electrolytic chrome applied to the layer of bright or satin electrolytic nickel.

22. The magnesium alloy composite structure of claim 13 wherein the surface layer is formed of a material selected from the group consisting of: Aluminum Titanium Nitride, Boron Nitride, Chromium Nitride, Titanium Nitride, Zirconium Nitride, Zirconium Oxide, Zirconium Oxycarbide, Titanium Carbide, Titanium Nitride and Diamond Like Carbon.
